(19) United States
(12) Patent Application Publication
(10) Pub. No.: US 2024/0145444 A1
(43) Pub. Date: May 2, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Kiju Lee, Suwon-si (KR); Jinsu Kim, Suwon-si (KR); Hyunsuk Yang, Suwon-si (KR); Byoungwook Jang, Suwon-si (KR)

(73) Assignee: SAMSUNG ELECTRONICS CO., LTD., Suwon-si (KR)

(21) Appl. No.: 18/219,396

(22) Filed: Jul. 7, 2023

(30) Foreign Application Priority Data
Oct. 28, 2022 (KR) 10-2022-0141612

(51) Int. Cl. H01L 25/10; H01L 21/56; H01L 23/00; H01L 23/31; H01L 23/498

(52) U.S. Cl. CPC H01L 25/105; H01L 21/565; H01L 23/3135; H01L 23/49822; H01L 23/49838; H01L 24/16; H01L 24/32; H01L 24/48; H01L 24/73; H01L 2224/16227; H01L 2224/16238; H01L 2224/32145; H01L 2224/32225; H01L 2224/48227; H01L 2224/73204; H01L 2224/73265; H01L 2225/1035; H01L 2225/1041; H01L 2225/1058; H01L 2924/1431; H01L 2924/1436; H01L 2924/1437; H01L 2924/1438

(57) ABSTRACT

A semiconductor package is provided and includes: a first redistribution structure including a first redistribution pattern and a first redistribution insulating layer, wherein the first redistribution pattern includes a first redistribution via extending in a vertical direction within the first redistribution insulating layer; a second redistribution structure on the first redistribution structure and including a second redistribution pattern and a second redistribution insulating layer, wherein the second redistribution pattern includes a lower redistribution pad at a lower surface of the second redistribution insulating layer; a first semiconductor chip on the second redistribution structure; and a second semiconductor chip on the first semiconductor chip. An upper surface of the first redistribution insulating layer is in contact with the lower surface of the second redistribution insulating layer, and the the first redistribution via of the first redistribution structure is in contact with the lower redistribution pad of the second redistribution structure.

### CROSS-REFERENCE TO THE RELATED APPLICATION

This application is based on and claims priority under 35 U.S.C. § 119 to Korean Patent Application No. 10-2022-0141612, filed on Oct. 28, 2022, in the Korean Intellectual Property Office, the disclosure of which is incorporated by reference herein in its entirety.

### BACKGROUND

Embodiments of the present disclosure relate to a semiconductor package and a manufacturing method thereof.

According to the rapid development of the electronics industry and user demands, electronic devices are being further miniaturized, multi-functional, and have large capacity. Accordingly, a semiconductor package including a plurality of semiconductor chips is required. For example, a method of mounting several types of semiconductor chips side by side on a package substrate, a method of stacking semiconductor chips or packages on one package substrate, or a method of mounting an interposer on which a plurality of semiconductor chips are mounted is used.

### SUMMARY

According to embodiments of the present disclosure, a semiconductor package and a manufacturing method thereof are provided.

According to embodiments of the present disclosure, a semiconductor package is provided. The semiconductor package includes: a first redistribution structure including a first redistribution pattern and a first redistribution insulating layer, wherein the first redistribution pattern includes a first redistribution via extending in a vertical direction within the first redistribution insulating layer; a second redistribution structure on the first redistribution structure and including a second redistribution pattern and a second redistribution insulating layer, wherein the second redistribution pattern includes a lower redistribution pad at a lower surface of the second redistribution insulating layer; a first semiconductor chip on the second redistribution structure; and a second semiconductor chip on the first semiconductor chip. An upper surface of the first redistribution insulating layer is in contact with the lower surface of the second redistribution insulating layer. The first redistribution via of the first redistribution structure is in contact with the lower redistribution pad of the second redistribution structure.

According to embodiments of the present disclosure, a semiconductor package is provided. The semiconductor package includes: a first redistribution structure including a first redistribution pattern and a first redistribution insulating layer, wherein the first redistribution pattern includes a first redistribution via extending in a vertical direction from an upper surface of the first redistribution insulating layer; a sub package on a central portion of the first redistribution structure; a frame substrate on an outer portion of the first redistribution structure and including a frame body having a through hole accommodating the sub package, and the frame substrate further including a vertical connection conductor extending in the vertical direction within the frame body; and a package molding layer on the sub package within the through hole of the frame substrate. The sub package includes: a second redistribution structure including a second redistribution pattern and a second redistribution insulating layer, wherein the second redistribution pattern includes a lower redistribution pad at a lower surface of the second redistribution insulating layer; a first semiconductor chip on the second redistribution structure; a first molding layer at least partially surrounding the first semiconductor chip on the second redistribution structure; a third redistribution structure on the first semiconductor chip and the first molding layer and including a third redistribution pattern and a third redistribution insulating layer; a conductive post extending between the second redistribution structure and the third redistribution structure and electrically connecting the second redistribution pattern to the third redistribution pattern; and a second semiconductor chip on the third redistribution structure. The upper surface of the first redistribution insulating layer is in direct contact with the lower surface of the second redistribution insulating layer. The first redistribution via of the first redistribution structure is in direct contact with the lower redistribution pad of the second redistribution structure.

According to embodiments of the present disclosure, a semiconductor package is provided. The semiconductor package includes: a first redistribution structure including a first redistribution pattern and a first redistribution insulating layer, wherein the first redistribution pattern includes a first redistribution via extending in a vertical direction from an upper surface of the first redistribution insulating layer; a sub package on a central portion of the first redistribution structure; a frame substrate on an outer portion of the first redistribution structure and including a frame body having a through hole accommodating the sub package, and the frame substrate further including a vertical connection conductor extending in the vertical direction within the frame body; and a package molding layer on the sub package within the through hole of the frame substrate. The sub package includes: a second redistribution structure including a second redistribution pattern and a second redistribution insulating layer, wherein the second redistribution pattern includes a lower redistribution pad at a lower surface of the second redistribution insulating layer and a second redistribution via extending in the vertical direction within the second redistribution insulating layer; a first semiconductor chip on the second redistribution structure; a first connection bump electrically connecting the second redistribution pattern to the first semiconductor chip between the second redistribution structure and the first semiconductor chip; a first molding layer at least partially surrounding the first semiconductor chip on the second redistribution structure; a third redistribution structure on the first semiconductor chip and the first molding layer and including a third redistribution pattern and a third redistribution insulating layer; a conductive post extending between the second redistribution structure and the third redistribution structure and electrically connecting the second redistribution pattern to the third redistribution pattern; a second semiconductor chip on the third redistribution structure; a second connection bump electrically connecting the third redistribution pattern to the second semiconductor chip between the third redistribution structure and the second semiconductor chip; and a second molding layer at least partially surrounding the second semiconductor chip on the third redistribution structure. The upper surface of the first redistribution insulating layer is in direct contact with the lower surface of the second redistribution insulating layer. The first redistribution via directly contacts the lower redistribution pad of the second redistribution structure. The first redistribution via has a tapered shape in which a width thereof decreases towards the upper surface of the first redistribution insulating layer. The lower redistribution pad has a rectangular cross-sectional shape.

According to embodiments of the present disclosure, a manufacturing method of a semiconductor package is provided. The manufacturing method includes: preparing a sub package; disposing a frame substrate and the sub package on a support film; forming a package molding layer on the support film such that the package molding layer is on the frame substrate and the sub package; removing the support film; and forming a first redistribution structure, that includes a first redistribution pattern and a first redistribution insulating layer, on a surface of the frame substrate and on a surface of the sub package exposed by removing the support film. The preparing the sub package includes: forming a second redistribution structure that includes a second redistribution pattern and a second redistribution insulating layer, wherein the second redistribution pattern includes a lower redistribution pad at a lower surface of the second redistribution insulating layer; mounting a first semiconductor chip on the second redistribution structure; forming a first molding layer at least partially surrounding the first semiconductor chip; forming a third redistribution structure including a third redistribution pattern and a third redistribution insulating layer on the first semiconductor chip and the first molding layer; and mounting a second semiconductor chip on the third redistribution structure. An upper surface of the first redistribution insulating layer is in direct contact with the lower surface of the second redistribution insulating layer. The first redistribution structure includes a first redistribution via extending in a vertical direction within the first redistribution insulating layer, and the first redistribution via directly contacts the lower redistribution pad of the second redistribution structure.

### BRIEF DESCRIPTION OF THE DRAWINGS

Embodiments of the present disclosure will be more clearly understood from the following detailed description taken in conjunction with the accompanying drawings in which:

FIG. 1 is a cross-sectional view illustrating a semiconductor package according to embodiments of the present disclosure;

FIG. 2 is an enlarged view showing an enlarged area EX1 of FIG. 1;

FIG. 3 is an enlarged view showing an enlarged area EX2 of FIG. 1;

FIG. 4 is a cross-sectional view illustrating a semiconductor package according to embodiments of the present disclosure;

FIG. 5 is a cross-sectional view illustrating a semiconductor package according to embodiments of the present disclosure;

FIG. 6 is an enlarged view showing an enlarged area EX3 of FIG. 5;

FIG. 7 is a cross-sectional view illustrating a semiconductor package according to embodiments of the present disclosure;

FIG. 8 is a cross-sectional view illustrating a semiconductor package according to embodiments of the present disclosure;

FIG. 9 is a cross-sectional view illustrating a semiconductor package according to embodiments of the present disclosure;

FIGS. 10A to 10H are cross-sectional views illustrating a method of manufacturing a semiconductor package according to embodiments of the present disclosure; and

FIGS. 11A to 11G are cross-sectional views illustrating a method of manufacturing a semiconductor package according to embodiments of the present disclosure.

### DETAILED DESCRIPTION

Hereinafter, non-limiting example embodiments of the present disclosure will be described in detail with reference to the accompanying drawings. The same reference numerals are used for the same components in the drawings, and duplicate descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

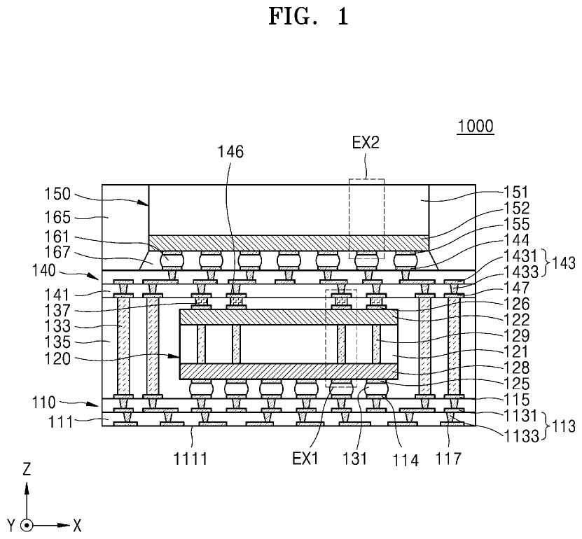

FIG. 1 is a cross-sectional view illustrating a semiconductor package 1000 according to embodiments of the present disclosure.

Referring to FIG. 1, the semiconductor package 1000 may include a lower redistribution structure 110, a first semiconductor chip 120, a first molding layer 135, conductive posts 133, conductive pillars 137, an upper redistribution structure 140, a second semiconductor chip 150, and a second molding layer 165.

The lower redistribution structure 110 may be a substrate on which the first semiconductor chip 120 is mounted. The lower redistribution structure 110 may include a lower redistribution pattern 113 and a lower redistribution insulating layer 111 covering the lower redistribution pattern 113.

Hereinafter, a direction parallel to the lower surface of the lower redistribution structure 110 is defined as a horizontal direction (e.g., the X direction and/or the Y direction), a direction perpendicular to the lower surface of the lower redistribution structure 110 is defined as a vertical direction (e.g., the Z direction), a horizontal width is defined as a length along the horizontal direction (e.g., the X direction and/or the Y direction), and a vertical level is defined as a height level along the vertical direction (e.g., the Z direction).

The lower redistribution insulating layer 111 may be formed from a material film made of an organic compound. The lower redistribution insulating layer 111 may include an insulating material of a Photo Imageable Dielectric (PID) material. For example, the lower redistribution insulating layer 111 may include photosensitive polyimide (PSPI). The lower redistribution insulating layer 111 may be composed of a plurality of insulating layers stacked in the vertical direction (e.g., the Z direction) or a single insulating layer.

The lower redistribution pattern 113 may include a plurality of lower redistribution conductive layers 1131 extending in the horizontal direction (e.g., the X direction and/or the Y direction), and a plurality of lower redistribution vias 1133 extending at least partially through the lower redistribution insulating layer 111. The plurality of lower redistribution conductive layers 1131 may extend along at least one of upper and lower surfaces of each of the insulating layers constituting the lower redistribution insulating layer 111. The plurality of lower redistribution vias 1133 may electrically connect the lower redistribution conductive layers 1131 at different vertical levels to each other.

Among the plurality of lower redistribution conductive layers 1131, the lowermost one of the lower redistribution conductive layer 1131 may include at least one lower redistribution pad 117 extending along the lower surface 1111 of the lower redistribution insulating layer 111. In example embodiments, when viewing a cross-section, the lower redistribution pad 117 may have a rectangular shape. Among the plurality of lower redistribution conductive layers 1131, the uppermost one of the lower redistribution conductive layers 1131 may include first upper redistribution pads 114 electrically connected to the first semiconductor chip 120, and may further include second upper redistribution pads 115 electrically connected to the conductive posts 133. In example embodiments, each of the plurality of lower redistribution vias 1133 may have a tapered shape in which a horizontal width thereof decreases towards the lower surface 1111 of the lower redistribution insulating layer 111.

The lower redistribution pattern 113 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof. A seed metal layer may be disposed between the lower redistribution pattern 113 and the lower redistribution insulating layer 111.

The first semiconductor chip 120 may be mounted on the lower redistribution structure 110. Between the first semiconductor chip 120 and the lower redistribution structure 110, a plurality of first connection bumps 131 that physically and electrically connect the first semiconductor chip 120 to the lower redistribution pattern 113 of the lower redistribution structure 110 may be disposed. The upper portion of each of the first connection bumps 131 may be connected to a corresponding first lower connection pad 125 among first lower connection pads 125 provided on a lower surface of the first semiconductor chip 120, and the lower portion of each of the first connection bumps 131 may be connected to a corresponding first upper redistribution pad 114 among first upper redistribution pads 114 of the lower redistribution structure 110. For example, each of the first connection bumps 131 may include metal, for example, solder.

The first molding layer 135 may be disposed on the lower redistribution structure 110 and may at least partially surround the first semiconductor chip 120. The first molding layer 135 may contact sidewalls, upper surfaces, and lower surfaces of the first semiconductor chip 120 and may extend along sidewalls, lower surfaces, and upper surfaces of the first semiconductor chip 120. The first molding layer 135 may fill a gap between the first semiconductor chip 120 and the lower redistribution structure 110 and may surround sidewalls of the plurality of first connection bumps 131. The first molding layer 135 may include an insulating polymer or an epoxy resin. For example, the first molding layer 135 may include an epoxy mold compound (EMC) or an insulating build-up film.

The upper redistribution structure 140 may be disposed on the first semiconductor chip 120 and the first molding layer 135. The upper redistribution structure 140 may include an upper redistribution pattern 143 and an upper redistribution insulating layer 141 covering the upper redistribution pattern 143.

The upper redistribution insulating layer 141 may be composed of a plurality of insulating layers stacked in a vertical direction (e.g., the Z direction) or a single insulating layer. A material of the upper redistribution insulating layer 141 may be substantially the same as a material of the lower redistribution insulating layer 111.

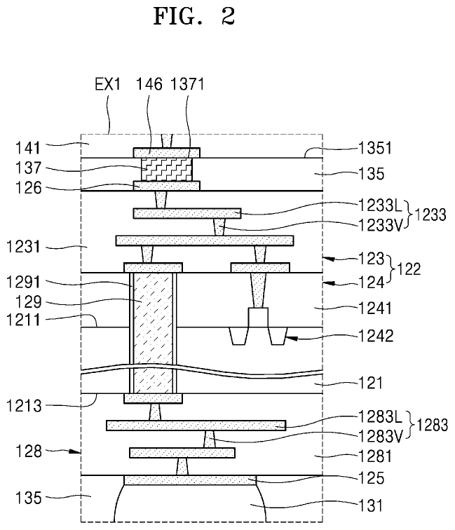

The upper redistribution pattern 143 may include a plurality of upper redistribution conductive layers 1431 extending in the horizontal direction (e.g., the X direction and/or the Y direction) and a plurality of upper redistribution vias 1433 extending at least partially through the upper redistribution insulating layers 141. The plurality of upper redistribution conductive layers 1431 may extend along at least one of upper and lower surfaces of each of the insulating layers constituting the upper redistribution insulating layer 141. The plurality of upper redistribution vias 1433 may electrically connect the upper redistribution conductive layers 1431 at different vertical levels to each other. Among the plurality of upper redistribution conductive layers 1431, the lowermost one of the upper redistribution conductive layer 1431 may include first lower redistribution pads 146 (refer to FIG. 2) and second lower redistribution pads 147. The first lower redistribution pads 146 and the second lower redistribution pads 147 may be provided at the lower surface of the upper redistribution insulating layer 141 and may extend along the lower surface of the upper redistribution insulating layer 141. The uppermost one of the upper redistribution conductive layers 1431 may include upper redistribution pads 144 electrically connected to the second semiconductor chip 150. In example embodiments, each of the plurality of upper redistribution vias 1433 may have a tapered shape in which a horizontal width thereof decreases towards the lower surface of the upper redistribution insulating layer 141. The material of the upper redistribution pattern 143 may be substantially the same as the material of the lower redistribution pattern 113.

The conductive posts 133 may vertically penetrate the first molding layer 135 and extend from the lower redistribution structure 110 to the upper redistribution structure 140. The conductive posts 133 may electrically connect the lower redistribution pattern 113 of the lower redistribution structure 110 to the upper redistribution pattern 143 of the upper redistribution structure 140. The lower portion of each of the conductive posts 133 may be connected to a corresponding second upper redistribution pad 115 from among the second upper redistribution pads 115 of the lower redistribution structure 110, and the upper portion of each of the conductive posts 133 may be connected to a corresponding second lower redistribution pad 147 among the second lower redistribution pads 147 of the upper redistribution structure 140. Each of the conductive posts 133 may include a metal, such as copper (Cu), aluminum (Al), and/or gold (Au). In example embodiments, the conductive posts 133 may be formed through a plating process.

The conductive pillars 137 may extend in a vertical direction (e.g., the Z direction) from an upper surface of the first semiconductor chip 120 to a lower surface of the upper redistribution structure 140. Each of the conductive pillars 137 may electrically connect the first semiconductor chip 120 to the upper redistribution pattern 143 of the upper redistribution structure 140. The lower part of each of the conductive pillars 137 may be connected to a corresponding first upper connection pad 126 among first upper connection pads 126 provided on the upper surface of the first semiconductor chip 120, and the upper portion of each of the conductive pillars 137 may be connected to a corresponding first lower redistribution pad 146 among the first lower redistribution pads 146 of the upper redistribution structure 140. Each of the conductive pillars 137 may include a metal, such as copper (Cu), aluminum (Al), and/or gold (Au). In example embodiments, the conductive pillars 137 may be formed through a plating process.

In embodiments, an upper surface 1351 (refer to FIG. 2) of the first molding layer 135, the upper surfaces 1371 (refer to FIG. 2) of the conductive pillars 137, and the upper surfaces of the conductive posts 133 may come into contact with the lower surface of the upper redistribution structure 140. In example embodiments, the upper surface 1351 of the first molding layer 135, the upper surfaces 1371 of the conductive pillars 137, and upper surfaces of the conductive posts 133 may be coplanar with each other.

The second semiconductor chip 150 may be mounted on the upper redistribution structure 140. Between the second semiconductor chip 150 and the upper redistribution structure 140, a plurality of second connection bumps 161 that physically and electrically connect the second semiconductor chip 150 to the upper redistribution pattern 143 of the upper redistribution structure 140 may be disposed. The upper portion of each of the second connection bumps 161 may be connected to a corresponding second lower connection pad 155 among second lower connection pads 155 provided on the lower surface of the second semiconductor chip 150, and the lower portion of each of the second connection bumps 161 may be connected to a corresponding upper redistribution pad 144 among the upper redistribution pads 144 of the upper redistribution structure 140. For example, each of the second connection bumps 161 may include metal, for example, solder.

In example embodiments, an underfill material layer 167 may be disposed between the second semiconductor chip 150 and the upper redistribution structure 140. The underfill material layer 167 may fill a gap between the second semiconductor chip 150 and the upper redistribution structure 140 and may surround sidewalls of the second connection bumps 161. The underfill material layer 167 may include an epoxy resin.

In example embodiments, each of the first semiconductor chip 120 and the second semiconductor chip 150 may include a logic chip and/or a memory chip. The logic chip may include a central processing unit (CPU) chip, a graphics processing unit (GPU) chip, an application processor (AP) chip, and an application specific integrated circuit (ASIC) chip. The memory chip may include a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip. The first semiconductor chip 120 and the second semiconductor chip 150 may be semiconductor chips of the same type or semiconductor chips of different types. In example embodiments, the first semiconductor chip 120 and the second semiconductor chip 150 may be logic chips. In example embodiments, one of the first semiconductor chip 120 and the second semiconductor chip 150 may be a logic chip and the other may be a memory chip.

The second molding layer 165 may be disposed on the upper redistribution structure 140 and may at least partially surround the second semiconductor chip 150. The second molding layer 165 may contact the sidewall of the second semiconductor chip 150 and may extend along the sidewall of the second semiconductor chip 150. In example embodiments, the second molding layer 165 may not cover the upper surface of the second semiconductor chip 150, and an upper surface of the second molding layer 165 may be coplanar with an upper surface of the second semiconductor chip 150. In example embodiments, the second molding layer 165 may cover the upper surface of the second semiconductor chip 150. The second molding layer 165 may include an insulating polymer or an epoxy resin. For example, the second molding layer 165 may include an EMC.

In the semiconductor package 1000, a footprint of the lower redistribution structure 110 and a footprint of the upper redistribution structure 140 may be identical to each other. A footprint of the lower redistribution structure 110 and a footprint of the upper redistribution structure 140 may be the same as the footprint of the semiconductor package 1000. For example, when viewing a cross-section, the horizontal width of the lower redistribution structure 110 and the horizontal width of the upper redistribution structure 140 are equal to each other, and sidewalls of the lower redistribution structure 110 may be aligned with sidewalls of the upper redistribution structure 140 in a vertical direction (e.g., the Z direction). In embodiments, when viewing a cross-section, the sidewall of the lower redistribution structure 110, the sidewall of the upper redistribution structure 140, the sidewall of the first molding layer 135, and the sidewall of the second molding layer 165 may be aligned with one another in a vertical direction (e.g., the Z direction). In example embodiments, the footprint of the second semiconductor chip 150 may be greater than the footprint of the first semiconductor chip 120. For example, when viewing a cross-section, the horizontal width of the second semiconductor chip 150 may be greater than the horizontal width of the first semiconductor chip 120.

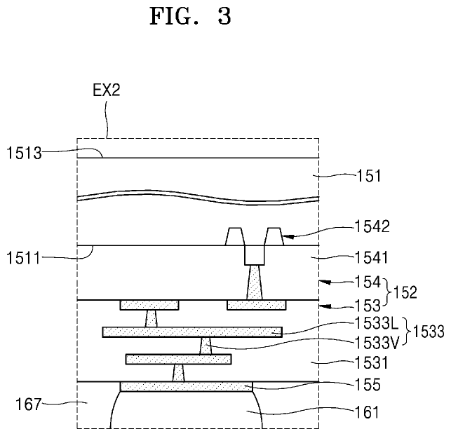

FIG. 2 is an enlarged view showing an enlarged area EX1 of FIG. 1. FIG. 3 is an enlarged view showing an enlarged area EX2 of FIG. 1.

Referring to FIGS. 1 to 3, the first semiconductor chip 120 may include a first semiconductor substrate 121, a first active layer 122, a first backside interconnect structure 128, and a first through electrode 129.

The first semiconductor substrate 121 may include a first active surface 1211 and a first inactive surface 1213 opposite to each other. The first active surface 1211 of the first semiconductor substrate 121 may correspond to an upper surface of the first semiconductor substrate 121 facing towards the second semiconductor chip 150, and the first inactive surface 1213 of the first semiconductor substrate 121 may correspond to a lower surface of the first semiconductor substrate 121 facing towards the lower redistribution structure 110.

The first semiconductor substrate 121 may be formed from a semiconductor wafer. The first semiconductor substrate 121 may include, for example, silicon (Si). Alternatively, the first semiconductor substrate 121 may include a semiconductor element, such as germanium (Ge), or a compound semiconductor, such as silicon carbide (SiC), gallium arsenide (GaAs), indium arsenide (InAs), and indium phosphide (InP). The first semiconductor substrate 121 may include a conductive region, for example, a well doped with an impurity or a structure doped with an impurity. Also, the first semiconductor substrate 121 may have various device isolation structures, such as a shallow trench isolation (STI) structure.

The first active layer 122 may be formed on the first active surface 1211 of the first semiconductor substrate 121. The first active layer 122 may include individual devices, such as circuit patterns and transistors. The first active layer 122 may include a first front end of line (FEOL) structure 124 disposed on the first active surface 1211 of the first semiconductor substrate 121 and a first front-side interconnect structure 123 disposed on the first FEOL structure 124.

The first FEOL structure 124 may include an insulating layer 1241 and various types of first individual devices 1242. The insulating layer 1241 may be disposed on the first active surface 1211 of the first semiconductor substrate 121. The insulating layer 1241 may include a plurality of interlayer insulating layers sequentially stacked on the first active surface 1211 of the first semiconductor substrate 121. The first individual devices 1242 may be formed in the first semiconductor substrate 121 and/or on the first active surface 1211 of the first semiconductor substrate 121. The first individual devices 1242 may include, for example, transistors. The first individual devices 1242 may include microelectronic devices, such as a metal-oxide-semiconductor field effect transistor (MOSFET), a system large scale integration (LSI), an image sensor, such as a complementary metal-oxide-semiconductor (CMOS) imaging sensor (CIS), a micro-electro-mechanical system (MEMS), an active device, a passive device, and the like. The first individual devices 1242 may be electrically connected to a conductive region of the first semiconductor substrate 121. Each of the first individual devices 1242 may be electrically separated from neighboring first individual devices 1242 by the insulating layer 1241.

The first front-side interconnect structure 123 may include a back end of line (BEOL) structure formed on the first FEOL structure 124. A footprint of the first front-side interconnect structure 123 may be the same as the footprint of the first FEOL structure 124 and the footprint of the first semiconductor substrate 121. The first front-side interconnect structure 123 may include a first interconnect insulating layer 1231 and a first interconnect pattern 1233 covered by the first interconnect insulating layer 1231. The first interconnect pattern 1233 may be electrically connected to the first individual devices 1242 and the conductive region of the first semiconductor substrate 121. The first interconnect pattern 1233 may include a plurality of first conductive layers 1233L extending in the horizontal direction (e.g., the X direction and/or the Y direction) and a plurality of first vias 1233V extending to at least partially penetrate the first interconnect insulating layer 1231. The plurality of first conductive layers 1233L may include first upper connection pads 126 provided on and/or in an upper surface of the first interconnect insulating layer 1231. The plurality of first vias 1233V may electrically connect to the first conductive layers 1233L at different vertical levels to each other. In example embodiments, each of the plurality of first vias 1233V may have a tapered shape in which a horizontal width thereof decreases towards the first active surface 1211 of the first semiconductor substrate 121. The first interconnect pattern 1233 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

The first backside interconnect structure 128 may be disposed on the first inactive surface 1213 of the first semiconductor substrate 121. A footprint of the first backside interconnect structure 128 may be the same as that of the first semiconductor substrate 121. The first backside interconnect structure 128 may include a first backside interconnect insulating layer 1281 and a first backside interconnect pattern 1283 covered by the first backside interconnect insulating layer 1281. The first backside interconnect pattern 1283 may include a plurality of first backside conductive layers 1283L extending in the horizontal direction (e.g., the X direction and/or the Y direction) and a plurality of first backside vias 1283V extending to at least partially penetrate the first backside interconnect insulating layer 1281. The plurality of first backside conductive layers 1283L may include first lower connection pads 125 provided on and/or in a lower surface of the first backside interconnect insulating layer 1281. The plurality of first backside vias 1283V may electrically connect the first backside conductive layers 1283L at different vertical levels to each other. In example embodiments, each of the plurality of first backside vias 1283V may have a tapered shape in which a horizontal width thereof decreases towards the first inactive surface 1213 of the first semiconductor substrate 121. For example, a material of the first backside interconnect pattern 1283 may be substantially the same as or similar to a material of the first interconnect pattern 1233.

The first through electrode 129 may vertically penetrate the first semiconductor substrate 121. The first through electrode 129 may electrically connect the first interconnect pattern 1233 of the first front-side interconnect structure 123 to the first backside interconnect pattern 1283 of the first backside interconnect structure 128. The first through electrode 129 may be provided in a through hole of the first semiconductor substrate 121, and a via insulation layer 1291 may be disposed between the first through electrode 129 and the first semiconductor substrate 121. For example, the first through electrode 129 may include a pillar-shaped conductive plug and a conductive barrier layer surrounding a sidewall of the conductive plug. The conductive plug may include, for example, at least one material selected from copper (Cu), nickel (Ni), gold (Au), silver (Ag), tungsten (W), titanium (Ti), tantalum (Ta), indium (In), molybdenum (Mo), manganese (Mn), Among cobalt (Co), tin (Sn), magnesium (Mg), rhenium (Re), beryllium (Be), gallium (Ga), and ruthenium (Ru). The conductive barrier layer may include at least one material selected from titanium (Ti), titanium nitride (TiN), tantalum (Ta), tantalum nitride (TaN), tungsten (W), tungsten nitride (WN), ruthenium (Ru), and cobalt (Co).

The second semiconductor chip 150 may include a second semiconductor substrate 151 and a second active layer 152.

The second semiconductor substrate 151 may include a second active surface 1511 and a second inactive surface 1513 opposite to each other (refer to FIG. 3). The second active surface 1511 of the second semiconductor substrate 151 may be the lower surface of the second semiconductor substrate 151 facing towards the first semiconductor chip 120, and the second inactive surface 1513 of the second semiconductor substrate 151 may be an upper surface of the second semiconductor substrate 151 facing towards the upper redistribution structure 140. A material of the second semiconductor substrate 151 may be substantially the same as or similar to a material of the first semiconductor substrate 121. The second semiconductor substrate 151 may include a conductive region, for example, a well doped with an impurity or a structure doped with an impurity. In addition, the second semiconductor substrate 151 may have various device isolation structures, such as an STI structure.

The second active layer 152 may be formed on the second active surface 1511 of the second semiconductor substrate 151. The second active layer 152 may include individual devices, such as circuit patterns and transistors. The second active layer 152 may include a second FEOL structure 154 disposed on the second active surface 1511 of the second semiconductor substrate 151, and may further include a second interconnect structure 153 disposed on the second FEOL structure 154.

The second FEOL structure 154 may include a second insulating layer 1541 and various types of second individual devices 1542. The second insulating layer 1541 may be disposed on the second active surface 1511 of the second semiconductor substrate 151. The second insulating layer 1541 may include a plurality of interlayer insulating layers sequentially stacked on the second active surface 1511 of the second semiconductor substrate 151. The second individual devices 1542 may be formed in the second semiconductor substrate 151 and/or on the second active surface 1511 of the second semiconductor substrate 151. The second individual devices 1542 may include, for example, transistors. The second individual devices 1542 may include microelectronic devices, for example, image sensors, such as MOSFETs, system LSIs, and CIS, MEMS, active devices, and passive devices. The second individual devices 1542 may be electrically connected to the conductive region of the second semiconductor substrate 151. Each of the second individual devices 1542 may be electrically separated from neighboring second individual devices 1542 by the second insulating layer 1541.

The second interconnect structure 153 may include a BEOL structure connected to the second FEOL structure 154. A footprint of the second interconnect structure 153 may be the same as the footprint of the second FEOL structure 154 and the footprint of the second semiconductor substrate 151. The second interconnect structure 153 may include a second interconnect insulating layer 1531 and a second interconnect pattern 1533 covered by the second interconnect insulating layer 1531. The second interconnect pattern 1533 may be electrically connected to the second individual devices 1542 and the conductive region of the second semiconductor substrate 151. The second interconnect pattern 1533 may include a plurality of second conductive layers 1533L extending in the horizontal direction (e.g., the X direction and/or the Y direction) and a plurality of second vias 1533V extending to at least partially penetrate the second interconnect insulating layer 1531. The plurality of second conductive layers 1533L may include second lower connection pads 155 provided on a lower surface of the second interconnect insulating layer 1531. The plurality of second vias 1533V may electrically connect the second conductive layers 1533L at different vertical levels to each other. In example embodiments, each of the plurality of second vias 1533V may have a tapered shape in which a horizontal width thereof decreases towards the second active surface 1511 of the second semiconductor substrate 151. A material of the second interconnect pattern 1533 may be substantially the same as or similar to a material of the first interconnect pattern 1233.

The first semiconductor chip 120 may be configured to transmit and receive electrical signals to and from external devices through the lower redistribution structure 110 and the first connection bumps 131. Between the first semiconductor chip 120 and an external device, an input/output data signal, a control signal, a power signal, and/or a ground signal may be transmitted through an electrical path including the lower redistribution pattern 113 and the first connection bumps 131.

In embodiments, the second semiconductor chip 150 may be configured to transmit and receive electrical signals to and from an external device through the lower redistribution structure 110, the conductive posts 133, the upper redistribution structure 140, and the second connection bumps 161. Between the second semiconductor chip 150 and an external device, input/output data signals, control signals, power signals and/or ground signals may be transmitted through an electrical path including the lower redistribution pattern 113, the conductive posts 133, the upper redistribution pattern 143, and the second connection bumps 161. In example embodiments, the second semiconductor chip 150 may be configured to transmit and receive electrical signals to and from external devices through the first through electrode 129 of the first semiconductor chip 120. The second semiconductor chip 150 may be configured to transmit and receive signals to and from external devices through an electrical path including the lower redistribution pattern 113, the first connection bumps 131, the first through electrodes 129, the conductive pillars 137, the upper redistribution pattern 143, and the second connection bumps 161. Furthermore, the second semiconductor chip 150 may be electrically connected to the first semiconductor chip 120 through an electrical path including the second connection bumps 161, the upper redistribution pattern 143 of the upper redistribution structure 140, and the conductive pillars 137.

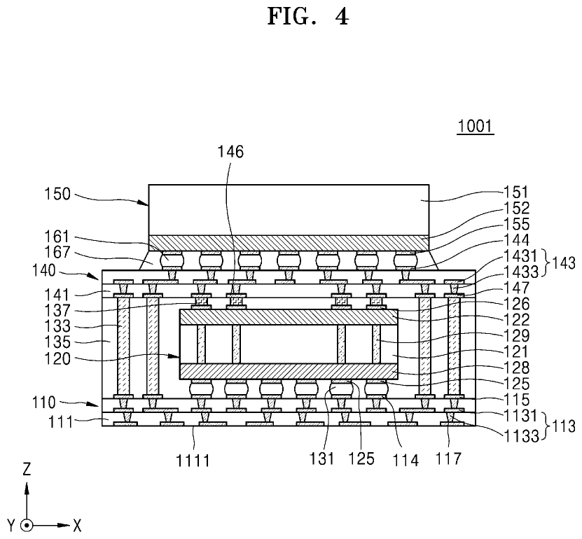

FIG. 4 is a cross-sectional view illustrating a semiconductor package 1001 according to embodiments of the present disclosure. Hereinafter, the semiconductor package 1001 shown in FIG. 4 is described focusing on the differences from the semiconductor package 1000 described with reference to FIG. 1.

Referring to FIG. 4, in the semiconductor package 1001, at least a portion of the second semiconductor chip 150 may be exposed to the outside of the semiconductor package 1001. Sidewalls and upper surfaces of the second semiconductor chip 150 may be exposed to the outside of the semiconductor package 1001. For example, the semiconductor package 1001 may be substantially the same as the semiconductor package 1000 described with reference to FIG. 1, except that the second molding layer 165 may be omitted.

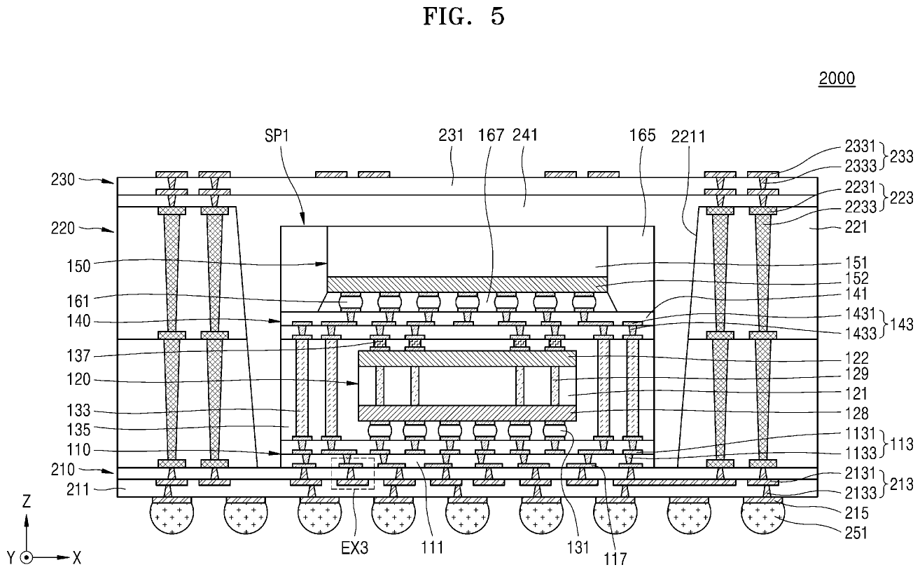

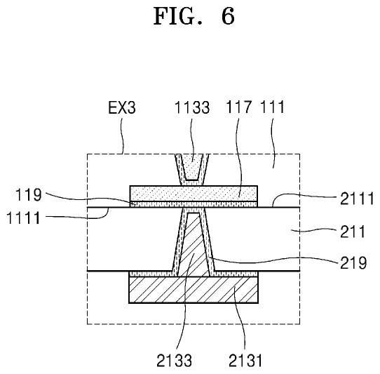

FIG. 5 is a cross-sectional view illustrating a semiconductor package 2000 according to embodiments of the present disclosure. FIG. 6 is an enlarged view showing an enlarged area EX3 of FIG. 5.

Referring to FIGS. 5 and 6, the semiconductor package 2000 may include a first redistribution structure 210, a sub package SP1, a frame substrate 220, a package molding layer 241, and a fourth redistribution structure 230.

The first redistribution structure 210 may be a substrate on which the sub package SP1 is mounted. The sub package SP1 may be disposed on the first redistribution structure 210 to cover a portion of the first redistribution structure 210. The sub package SP1 may be disposed on the central portion of the first redistribution structure 210. The sub package SP1 may be the semiconductor package 1000 described with reference to FIGS. 1 to 3. In the sub package SP1, the lower redistribution structure 110 may be referred to as a second redistribution structure, and the upper redistribution structure 140 may be referred to as a third redistribution structure. In the lower redistribution structure 110 of the sub package SP1, the lower redistribution pattern 113 may be referred to as a second redistribution pattern, and the lower redistribution insulating layer 111 may be referred to as a second redistribution insulating layer. In the upper redistribution structure 140 of the sub package SP1, the upper redistribution pattern 143 may be referred to as a third redistribution pattern, and the upper redistribution insulating layer 141 may be referred to as a third redistribution insulating layer.

The first redistribution structure 210 may include a first redistribution pattern 213 and a first redistribution insulating layer 211 covering the first redistribution pattern 213.

The first redistribution insulating layer 211 may be composed of a plurality of insulating layers stacked in the vertical direction (e.g., the Z direction) or a single insulating layer. The first redistribution insulating layer 211 may be formed from a material film made of an organic compound. For example, the first redistribution insulating layer 211 may include PSPI. In example embodiments, the material of the first redistribution insulating layer 211 may be the same as the material of the lower redistribution insulating layer 111 of the sub package SP1. In example embodiments, a material of the first redistribution insulating layer 211 may be different from a material of the lower redistribution insulating layer 111 of the sub package SP1.

The first redistribution pattern 213 may include a plurality of conductive layers 2131 extending in the horizontal direction (e.g., the X direction and/or the Y direction) and a plurality of first redistribution vias 2133 extending at least partially through the first redistribution insulating layer 211. The plurality of conductive layers 2131 may extend along at least one of upper and lower surfaces of each of the insulating layers constituting the first redistribution insulating layer 211. The plurality of first redistribution vias 2133 may electrically connect to the conductive layers 2131 at different vertical levels to each other. Among the plurality of conductive layers 2131, the lowermost one of the conductive layers 2131 may include external connection pads 215. The external connection pads 215 may extend along the lower surface of the first redistribution insulating layer 211. In example embodiments, each of the plurality of first redistribution vias 2133 may have a tapered shape in which a horizontal width thereof decreases towards the upper surface 2111 (refer to FIG. 6) of the first redistribution insulating layer 211. A material of the first redistribution pattern 213 may be substantially the same as a material of the lower redistribution pattern 113 of the sub package SP1. A seed metal layer 219 may be disposed between the first redistribution pattern 213 and the first redistribution insulating layer 211.

The semiconductor package 2000 may further include external connection terminals 251 attached to a lower surface of the first redistribution structure 210. The external connection terminals 251 may be respectively attached to the external connection pads 215 of the first redistribution structure 210. The external connection terminals 251 may include, for example, solder. The external connection terminal 251 may physically and electrically connect an external device to the semiconductor package 2000.

The frame substrate 220 may be disposed on an outer portion of the first redistribution structure 210. In embodiments, the frame substrate 220 may be a panel board. The frame substrate 220 may be, for example, a printed circuit board (PCB), a ceramic substrate, or a wafer for manufacturing a package. In embodiments, the frame substrate 220 may be a multi-layer PCB.

The frame substrate 220 may include a frame body 221, that is an insulating frame body, and a vertical connection conductor 223 provided in the frame body 221.

The frame body 221 may be made of at least one material selected from phenol resin, epoxy resin, and polyimide. For example, the frame body 221 may include at least one material selected from among flame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The frame substrate 220 may include a through hole 2211 configured to accommodate the sub package SP1. The through hole 2211 may vertically pass through the frame body 221 and may be defined by an inner sidewall of the frame body 221. The frame body 221 may surround the sub package SP1, and the vertical level of the upper surface of the frame substrate 220 may be higher than the vertical level of the upper surface of the sub package SP1. In example embodiments, the horizontal width of the through hole 2211 of the frame body 221 may decrease towards the first redistribution structure 210.

The vertical connection conductor 223 may electrically connect the first redistribution pattern 213 of the first redistribution structure 210 to a fourth redistribution pattern 233 of the fourth redistribution structure 230. In embodiments, the vertical connection conductor 223 may include a plurality of conductive layers 2231 extending in the horizontal direction (e.g., the X direction and/or the Y direction) and a plurality of conductive vias 2233 extending in a vertical direction (e.g., the Z direction). In example embodiments, the frame substrate 220 may be a multi-layer substrate in which the frame body 221 is composed of a plurality of layers. In this case, the plurality of conductive layers 2231 may be arranged spaced apart from each other at different vertical levels within the frame body 221. The plurality of conductive layers 2231 may extend on at least one of upper and lower surfaces of each of the plurality of layers constituting the frame body 221. The plurality of conductive vias 2233 may extend in the vertical direction (e.g., the Z direction) through at least a portion of the frame body 221, and may electrically connect the plurality of conductive layers 2231 at different vertical levels to each other. The vertical connection conductor 223 may include a metal, such as copper (Cu), aluminum (Al), tungsten (W), titanium (Ti), or tantalum (Ta).

The package molding layer 241 is disposed on the first redistribution structure 210 and may cover the frame substrate 220 and the sub package SP1. The package molding layer 241 may be referred to as a third molding layer. The package molding layer 241 may fill the through hole 2211 of the sub package SP1 and may extend along the sidewall of the sub package SP1 and the inner sidewall of the frame substrate 220. The package molding layer 241 may extend along the sidewall of the lower redistribution structure 110, the sidewall of the first molding layer 135, the sidewall of the upper redistribution structure 140, and the sidewall of the second molding layer 165, and may extend along the upper surface of the second molding layer 165 and the upper surface of the second semiconductor chip 150. Also, the package molding layer 241 may contact a portion of the upper surface of the first redistribution structure 210 extending between the sidewall of the sub package SP1 and the inner sidewall of the frame substrate 220. The package molding layer 241 may include an insulating polymer or an epoxy resin. For example, the package molding layer 241 may include an EMC or an insulating build-up film. In example embodiments, the material of the package molding layer 241 may be the same as the material of the first molding layer 135 and/or the material of the second molding layer 165. In example embodiments, a material of the package molding layer 241 may be different from a material of the first molding layer 135 and/or a material of the second molding layer 165.

The fourth redistribution structure 230 may be disposed on the package molding layer 241. The fourth redistribution structure 230 may include the fourth redistribution pattern 233 and a fourth redistribution insulating layer 231 covering the fourth redistribution pattern 233.

The fourth redistribution insulating layer 231 may be composed of a plurality of insulating layers stacked in the vertical direction (e.g., the Z direction) or a single insulating layer. A material of the fourth redistribution insulating layer 231 may be substantially the same as a material of the first redistribution insulating layer 211.

The fourth redistribution pattern 233 may include a plurality of conductive layers 2331 extending in the horizontal direction (e.g., the X direction and/or the Y direction) and a plurality of fourth redistribution vias 2333 extending at least partially through the fourth redistribution insulating layer 231. The plurality of conductive layers 2331 may extend along at least one of a surface of the fourth redistribution insulating layer 231 and an upper surface of the package molding layer 241. The plurality of fourth redistribution vias 2333 may electrically connect the conductive layers 2331 at different vertical levels to each other. Electronic components (e.g., semiconductor packages, semiconductor chips, passive components, etc.) may be mounted on the fourth redistribution structure 230. Among the plurality of conductive layers 2331, the conductive layer 2331 on the upper surface of the fourth redistribution insulating layer 231 may include a connection pad to which a connection terminal for connecting between the fourth redistribution structure 230 and the electronic component is attached. In example embodiments, each of the plurality of fourth redistribution vias 2333 may have a tapered shape in which a horizontal width thereof decreases towards the first redistribution structure 210. In example embodiments, some of the fourth redistribution vias 2333 among the plurality of fourth redistribution vias 2333 may penetrate the package molding layer 241 and extend in a vertical direction (e.g., the Z direction) and may contact the vertical connection conductor 223 of the frame substrate 220. A material of the fourth redistribution pattern 233 may be substantially the same as a material of the first redistribution pattern 213.

In embodiments of the present disclosure, the sub package SP1 may be directly attached to the upper surface of the first redistribution structure 210. A lower surface of the lower redistribution structure 110 may directly contact an upper surface of the first redistribution structure 210 so that a gap is not formed between the sub package SP1 and the first redistribution structure 210. When viewing a cross-section, between one side and the other side of the lower redistribution structure 110, the lower surface of the lower redistribution structure 110 may continuously contact the upper surface of the first redistribution structure 210. More specifically, the lower surface 1111 of the lower redistribution insulating layer 111 may directly contact the upper surface 2111 of the first redistribution insulating layer 211, and the lower redistribution pattern 113 may directly contact the first redistribution pattern 213 without any other conductive medium. In example embodiments, the first redistribution via 2133 of the first redistribution structure 210 may be directly connected to the lower redistribution pad 117 of the lower redistribution structure 110. In embodiments, the lower redistribution structure 110 may include a seed metal layer 119 extending along a lower surface of the lower redistribution pad 117, and the first redistribution structure 210 may include a seed metal layer 219 extending along the surface of the first redistribution via 2133, and the seed metal layer 119 of the lower redistribution structure 110 and the seed metal layer 219 of the first redistribution structure 210 may contact each other at a contact surface between the lower redistribution structure 110 and the first redistribution structure 210.

In a typical semiconductor package of a comparative embodiment, between the package substrate and the mounting component, a conductive medium (e.g., a solder bump) for electrically connecting the package substrate to the mounted component, and an underfill resin layer filling a gap between the package substrate and the mounted component are disposed. In the case of such a typical semiconductor package, the thickness of the semiconductor package inevitably increases as much as the height of the conductive medium, and in addition, there is an issue in which a void is formed between the package substrate and the mounted component due to a defect in the underfill process.

However, according to embodiments of the present disclosure, since the sub package SP1 including at least one semiconductor chip is directly connected to the first redistribution structure 210, the reliability of the semiconductor package 2000 may be prevented from being deteriorated due to defects in the underfill process and the size of the semiconductor package 2000 may be reduced by reducing the thickness of the semiconductor package 2000. Furthermore, within the preset dimensions of the semiconductor package 2000, since a conductive medium connecting the first redistribution structures 210 of the sub package SP1 is omitted, the thickness of the second semiconductor chip 150 may be increased by the reduced thickness, so that the heat dissipation efficiency of the second semiconductor chip 150 may be improved.

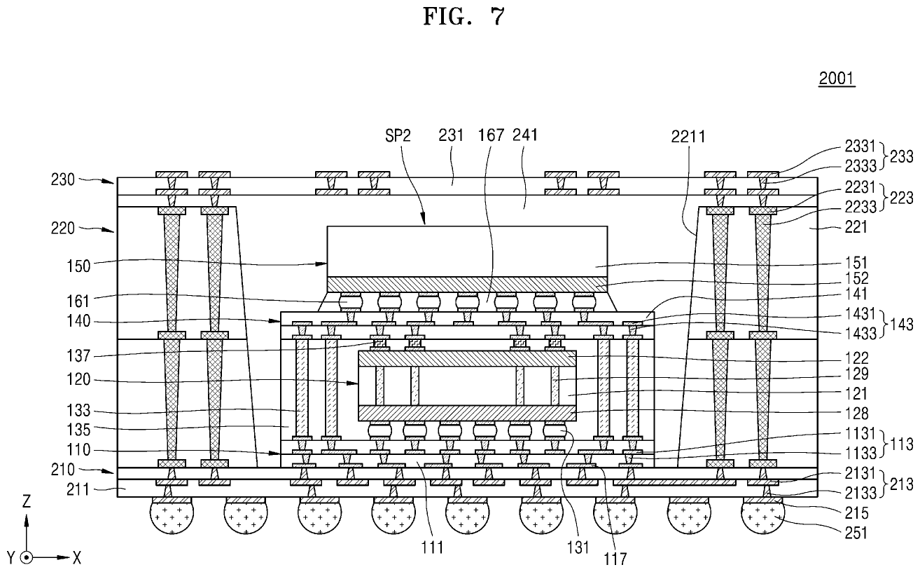

FIGS. 7 to 9 are cross-sectional views illustrating a semiconductor package 2001, a semiconductor package 2002, and a semiconductor package 2003 according to embodiments of the present disclosure. Hereinafter, the semiconductor package 2001, the semiconductor package 2002, and the semiconductor package 2003 illustrated in FIGS. 7 to 9 are described focusing on the differences from the semiconductor package 2000 described with reference to FIG. 5.

Referring to FIG. 7, in the semiconductor package 2001, the sub package SP2 may be the semiconductor package 1001 described with reference to FIG. 4. The package molding layer 241 may directly contact upper surfaces of the second semiconductor chip 150 and the upper redistribution structure 140. The package molding layer 241 may extend along the upper surface of the upper redistribution structure 140 and may extend along sidewalls and the upper surface of the second semiconductor chip 150.

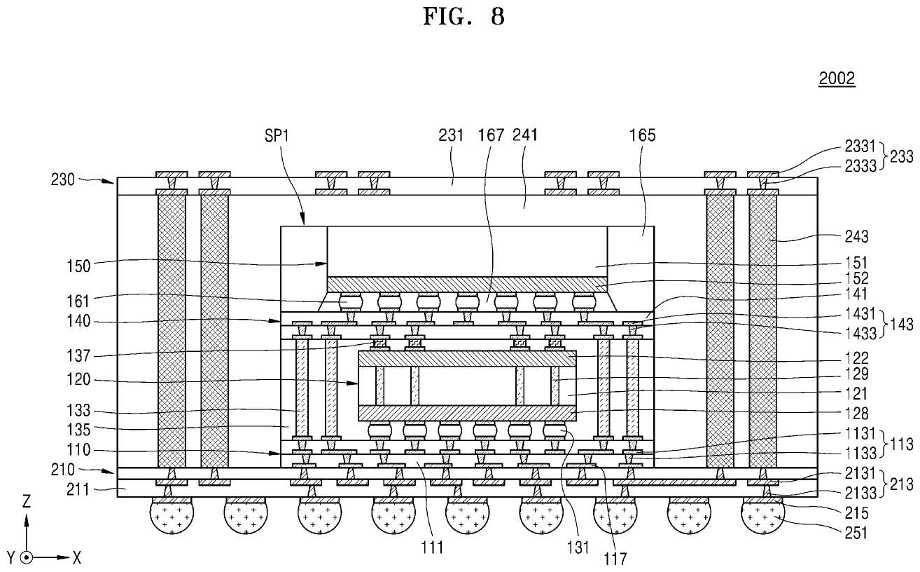

Referring to FIG. 8, in the semiconductor package 2002, the package molding layer 241 may cover an outer portion of the upper surface of the first redistribution structure 210. A sidewall of the package molding layer 241 may be vertically aligned with a sidewall of the first redistribution structure 210. A vertical connection conductor 243 may extend from the lower redistribution structure 110 to the upper redistribution structure 140 in a vertical direction (e.g., the Z direction) through the package molding layer 241. The vertical connection conductor 243 may have a pillar shape vertically penetrating the package molding layer 241. The vertical connection conductor 243 may include metal, for example copper. The vertical connection conductor 243 may be formed through a plating process.

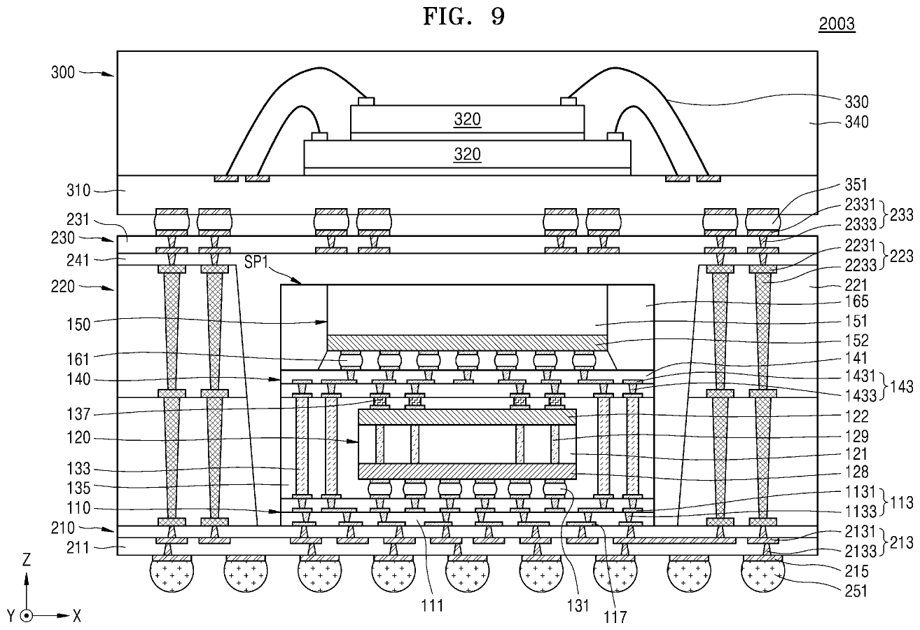

Referring to FIG. 9, a semiconductor package 2003 may include an upper semiconductor device 300 disposed on a fourth redistribution structure 230. The upper semiconductor device 300 may be mounted on the fourth redistribution structure 230 through the upper connection terminals 351. A lower portion of the upper connection terminals 351 may be coupled to the fourth redistribution pattern 233 of the fourth redistribution structure 230, and an upper portion of the upper connection terminals 351 may be coupled to the upper semiconductor device 300. The upper connection terminals 351 may electrically and physically connect the fourth redistribution structure 230 to the upper semiconductor device 300.

In example embodiments, the upper semiconductor device 300 may include an upper substrate 310, one or more third semiconductor chips 320 mounted on the upper substrate 310, an upper molding layer 340 covering the one or more third semiconductor chips 320 on the upper substrate 310, and at least one conductive connection member 330 electrically connecting the one or more third semiconductor chips 320 and the upper substrate 310. The upper substrate 310 may be, for example, a PCB. The conductive connection member 330 may include a conductive wire. The third semiconductor chips 320 may include a memory chip and/or a logic chip. In example embodiments, the third semiconductor chips 320 may be a memory chip, and at least one of the first semiconductor chip 120 and the second semiconductor chip 150 may be a logic chip. In example embodiments, at least one third semiconductor chip 320 may be directly mounted on the fourth redistribution structure 230 through a solder bump.

The first semiconductor chip 120 and the one or more third semiconductor chips 320 may be electrically connected to each other through an electrical connection path including the first connection bumps 131, the lower redistribution pattern 113, the first redistribution pattern 213, the vertical connection conductor 223, the fourth redistribution pattern 233, and the upper connection terminals 351. The second semiconductor chip 150 and the third semiconductor chip 320 may be electrically connected to each other through an electrical connection path including the second connection bumps 161, the upper redistribution pattern 143, the conductive posts 133, the lower redistribution pattern 113, the first redistribution pattern 213, the vertical connection conductor 223, the fourth redistribution pattern 233 and the upper connection terminals 351.

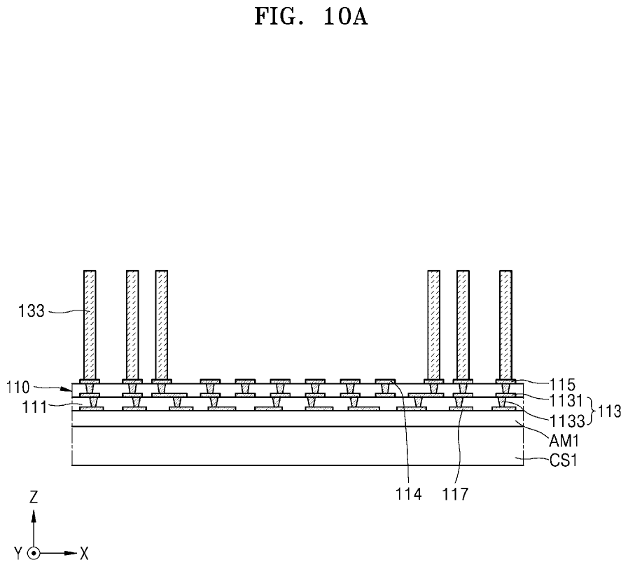

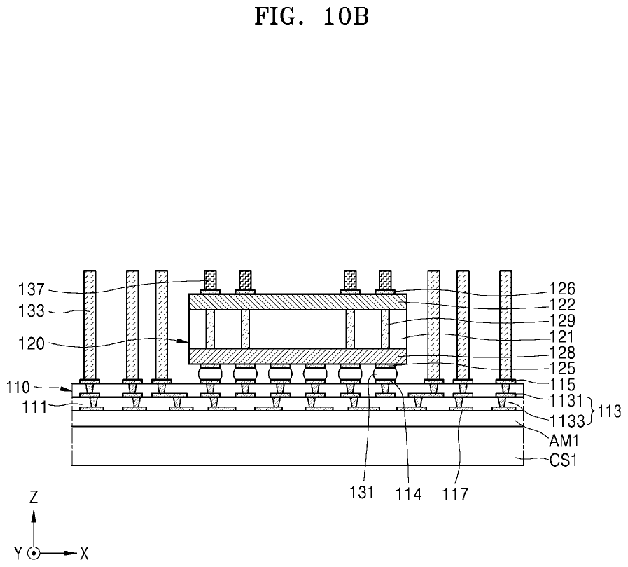

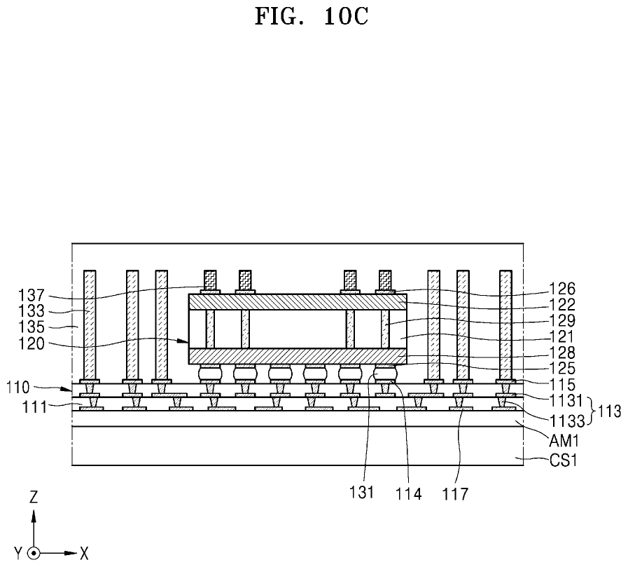

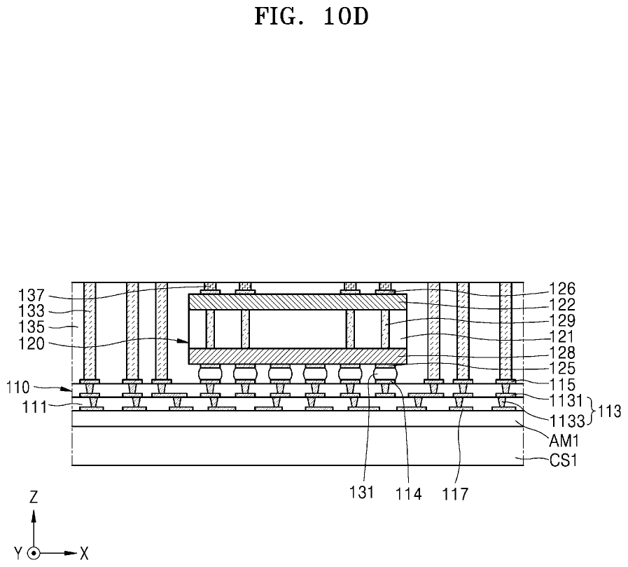

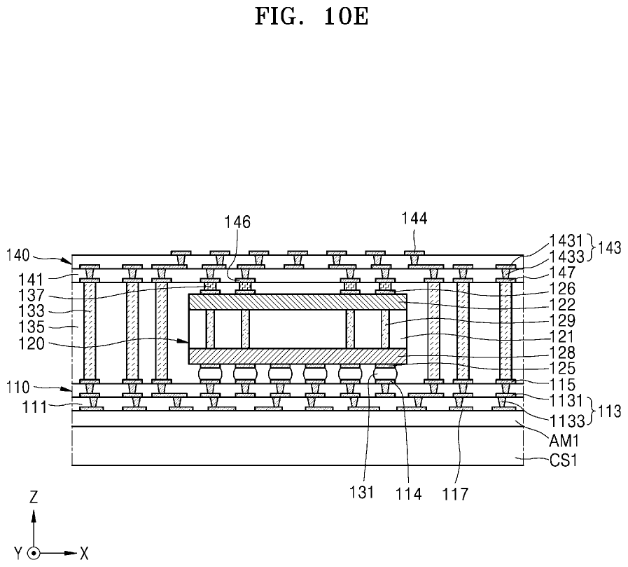

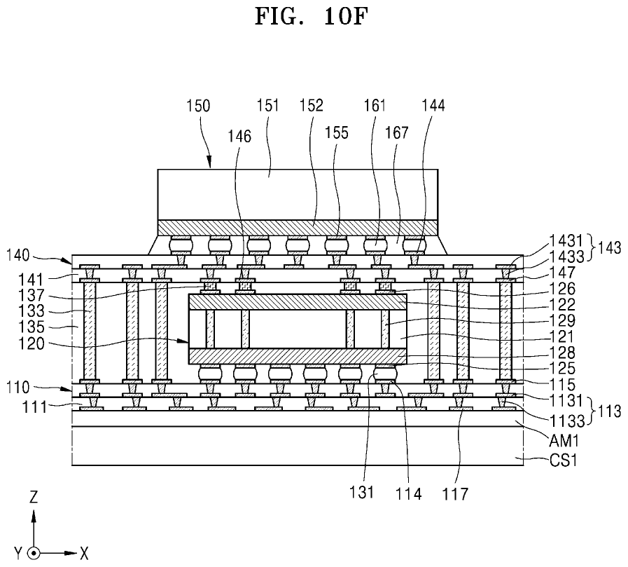

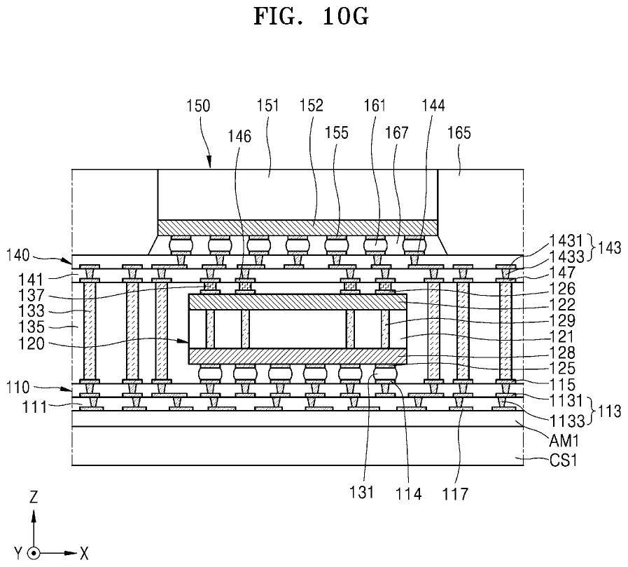

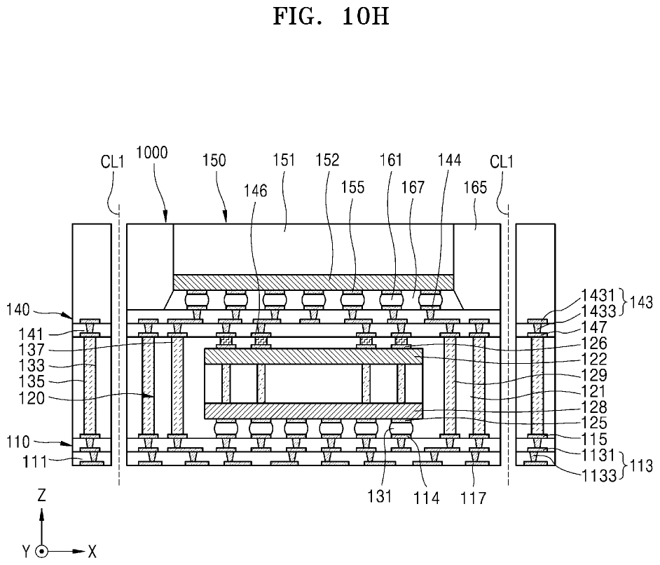

FIGS. 10A to 10H are cross-sectional views illustrating a method of manufacturing a semiconductor package 1000 according to embodiments of the present disclosure. Hereinafter, a method of manufacturing the semiconductor package 1000 described with reference to FIG. 1 will be described with reference to FIGS. 1 and 10A to 10H.

Referring to FIG. 10A, a first carrier substrate CS1 is prepared. The first carrier substrate CS1 may have a flat plate shape. When viewed in a plan view, the first carrier substrate CS1 may have circular or polygonal shape such as a quadrangle shape. The first carrier substrate CS1 may be, for example, a semiconductor substrate, a glass substrate, a ceramic substrate, or a plastic substrate. A first adhesive material layer AM1 may be applied on the first carrier substrate CS1.

Next, a lower redistribution structure 110 including a lower redistribution pattern 113 and a lower redistribution insulating layer 111 is formed on the first carrier substrate CS1. For example, sub insulating layers (e.g., first and second sub insulating layers) constituting the lower redistribution insulating layer 111 may be formed through a lamination process, respectively, and the lower redistribution pattern 113 may be formed through a plating process. For example, forming the lower redistribution structure 110 may include forming a first conductive layer including lower redistribution pads 117 on the upper surface of the first adhesive material layer AM1, forming a first sub insulating layer covering the conductive layer of the first layer, forming a lower redistribution via 1133 filling the via hole of the first sub insulation layer and a conductive layer of a second layer extending along an upper surface of the first sub insulation layer, forming a second sub insulating layer covering the first sub insulating layer, and forming a lower redistribution via 1133 filling the via hole of the second sub insulation layer and a third conductive layer extending along the upper surface of the second sub insulation layer. The conductive layer of the third layer disposed on the upper surface of the third sub insulating layer may include first upper redistribution pads 114 and second upper redistribution pads 115.

After forming the lower redistribution structure 110, conductive posts 133 are formed on the second upper redistribution pads 115 of the lower redistribution structure 110. The conductive posts 133 may be formed through a plating process.

Referring to FIG. 10B, a first semiconductor chip 120 having conductive pillars 137 is mounted on the lower redistribution structure 110. The first semiconductor chip 120 may be mounted on the lower redistribution structure 110 through the first connection bumps 131.

Referring to FIG. 10C, a first molding layer 135 is formed on the lower redistribution structure 110. The first molding layer 135 may be formed to cover the first semiconductor chip 120, the conductive pillars 137, and the conductive posts 133.

Referring to FIG. 10D, a portion of the first molding layer 135 may be removed to expose the conductive posts 133 and the conductive pillars 137. To remove a portion of the first molding layer 135, a chemical mechanical polishing (CMP) process, a grinding process, and/or an etch-back process may be performed. For example, a portion of the first molding layer 135, a portion of each of the conductive posts 133, and a portion of each of the conductive pillars 137 may be removed through a polishing process. In example embodiments, as a result of the polishing process, the polished surface of the first molding layer 135, the upper surfaces of the conductive posts 133, and the upper surfaces of the conductive pillars 137 may be coplanar with each other.

Referring to FIG. 10E, an upper redistribution structure 140 including an upper redistribution pattern 143 and an upper redistribution insulating layer 141 is formed on the first molding layer 135. For example, the sub insulating layers (e.g., the third and fourth sub insulating layers) constituting the upper redistribution insulating layer 141 may be formed through a lamination process, respectively, and the upper redistribution pattern 143 may be formed through a plating process. A method of forming the upper redistribution structure 140 is substantially the same as or similar to the method of forming the lower redistribution structure 110 described above, and thus a repeated description thereof is omitted here.

Referring to FIG. 10F, the second semiconductor chip 150 is mounted on the upper redistribution structure 140. The second semiconductor chip 150 may be mounted on the upper redistribution structure 140 by the second connection bumps 161. After mounting the second semiconductor chip 150 on the upper redistribution structure 140, an underfill process is performed so that an underfill material layer 167 filling a gap between the second semiconductor chip 150 and the upper redistribution structure 140 is formed.

Referring to FIG. 10G, a second molding layer 165 is formed on the upper redistribution structure 140 (e.g., the second upper redistribution structure). The second molding layer 165 may cover an upper surface of the upper redistribution structure 140 and may surround sidewalls of the second molding layer 165. In example embodiments, the second molding layer 165 may be formed not to cover the upper surface of the second semiconductor chip 150, and an upper surface of the second molding layer 165 and an upper surface of the second semiconductor chip 150 may be coplanar with each other.

Referring to FIGS. 10G and 10H, after separating the first carrier substrate CS1 from the first redistribution structure 210, a sawing process of cutting the panel-shaped structure shown in FIG. 10G along the cutting line CL1 may be performed. Through the sawing process, the panel-shaped structure shown in FIG. 10G may be separated into individual ones of a plurality of the semiconductor package 1000.

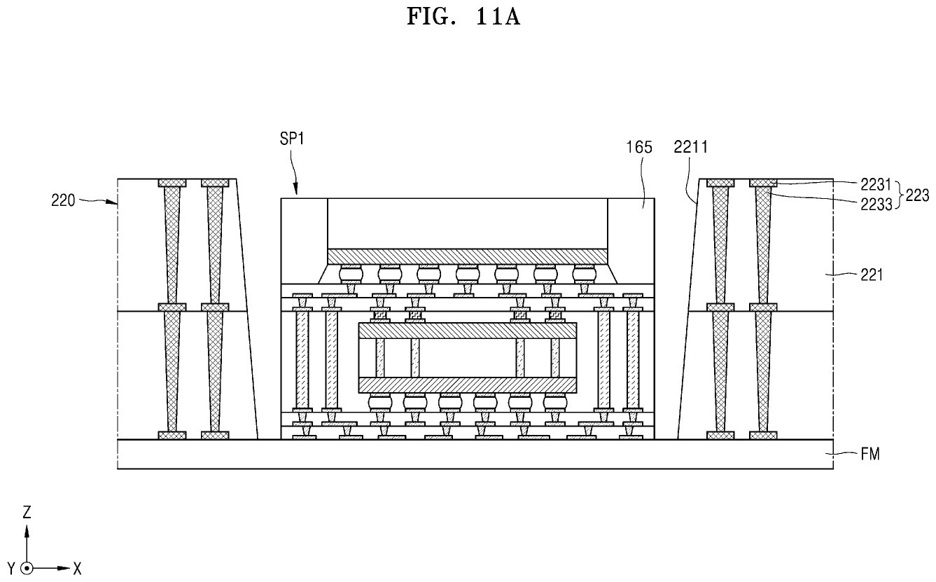

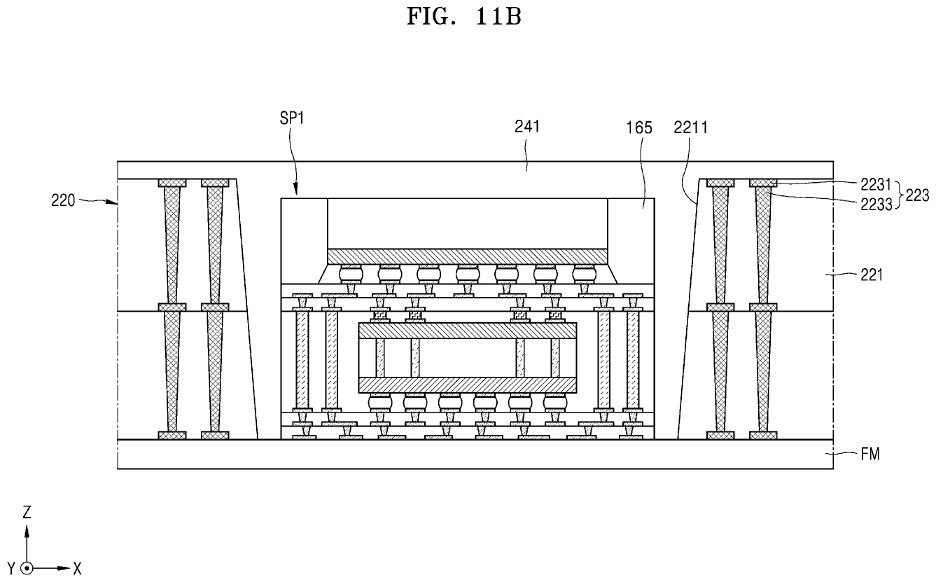

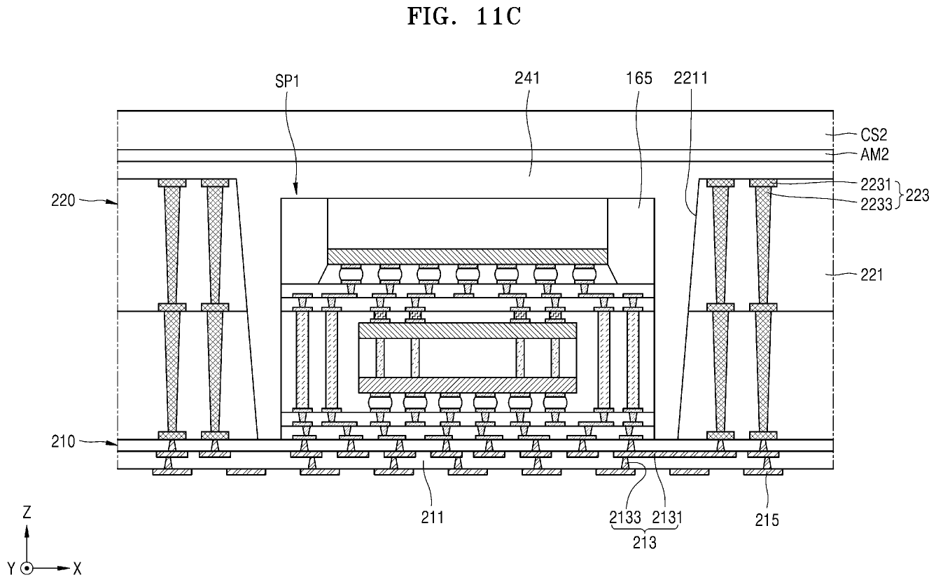

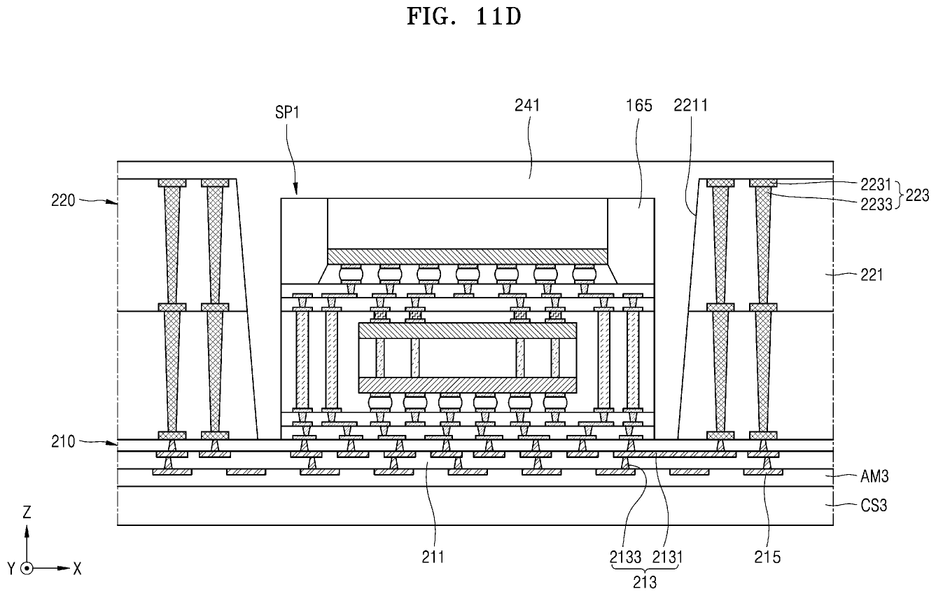

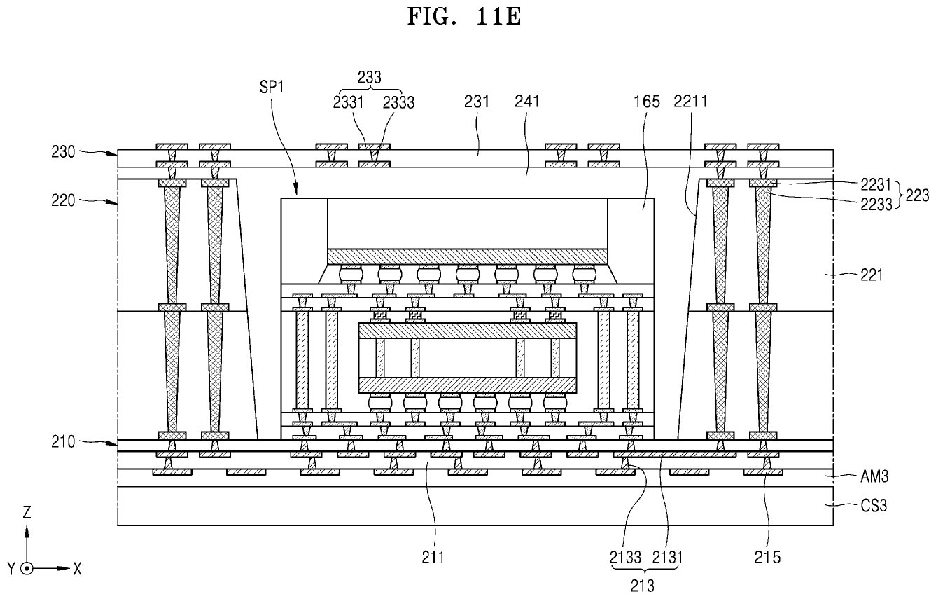

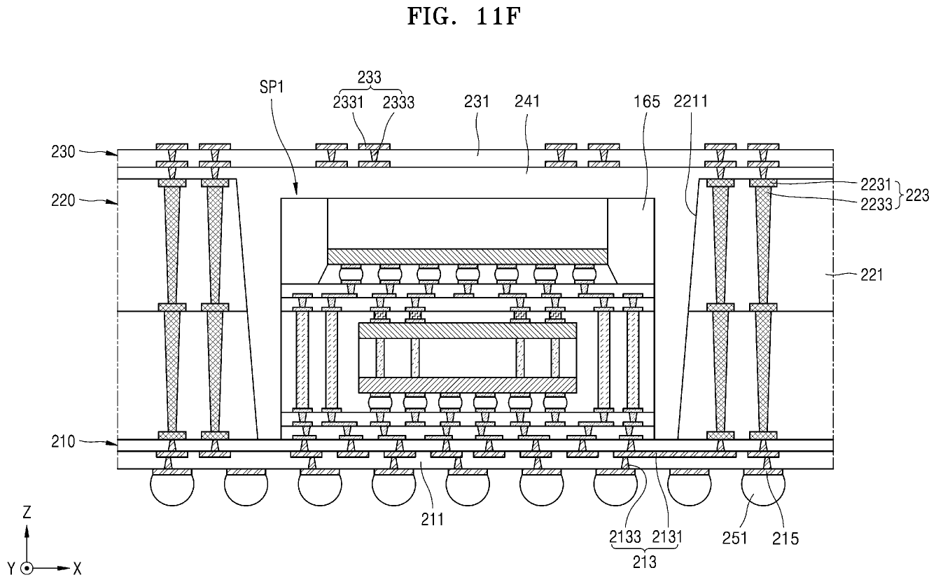

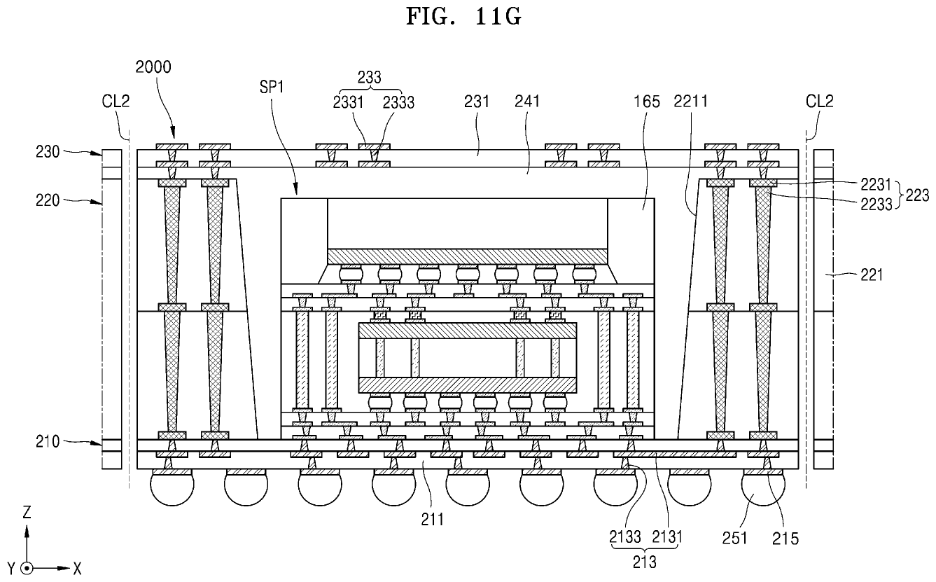

FIGS. 11A to 11G are cross-sectional views illustrating a method of manufacturing a semiconductor package 2000 according to embodiments of the present disclosure. Hereinafter, a method of manufacturing the semiconductor package 2000 described with reference to FIG. 5 will be described with reference to FIGS. 5 and 11A to 11G.

Referring to FIG. 11A, a support film FM is prepared, and a frame substrate 220 and a sub package SP1 are disposed on the support film FM. The frame substrate 220 and the sub package SP1 may be attached to and fixed to the support film FM. The sub package SP1 may be inserted into the through hole 2211 of the frame substrate 220.

Referring to FIG. 11B, a package molding layer 241 covering the frame substrate 220 and the sub package SP1 is formed on the support film FM. The package molding layer 241 may fill the through hole 2211 of the frame substrate 220 and cover the upper surface of the frame substrate 220.

Referring to FIGS. 11B and 11C, the second carrier substrate CS2 is attached to the upper surface of the package molding layer 241, and the support film FM is separated from the frame substrate 220 and the sub package SP1. The second carrier substrate CS2 may be, for example, a semiconductor substrate, a glass substrate, a ceramic substrate, or a plastic substrate. A second adhesive material layer AM2 may be disposed between the second carrier substrate CS2 and the package molding layer 241.

After attaching the second carrier substrate CS2 on the package molding layer 241, a first redistribution structure 210 including a first redistribution pattern 213 and a first redistribution insulating layer 211 is formed on the lower side of the frame substrate 220 and the sub package SP1. For example, the sub insulating layers (e.g., the fifth and sixth sub insulating layers) constituting the first redistribution insulating layer 211 may be formed through a lamination process, and the first redistribution pattern 213 may be formed through a plating process.

For example, forming the first redistribution structure 210 may include forming a fifth sub insulating layer extending along the lower surface of the frame substrate 220 and the lower surface of the sub package SP1, forming via holes exposing the lower redistribution pads 117 and the vertical connection conductors 223 of the frame substrate 220 in the fifth sub insulating layer, forming first redistribution vias 2133 filling the via holes of the fifth sub insulating layer and a conductive layer extending along the lower surface of the fifth sub insulating layer, forming a sixth sub insulating layer extending along the lower surface of the fifth sub insulating layer, and forming the first redistribution vias 2133 filling the via holes of the sixth sub insulating layer and a conductive layer extending along the lower surface of the sixth sub insulating layer.

Referring to FIGS. 11C and 11D, the second carrier substrate CS2 is separated by the package molding layer 241 and the third carrier substrate CS3 is attached to the lower side of the first redistribution structure 210. The third carrier substrate CS3 may be, for example, a semiconductor substrate, a glass substrate, a ceramic substrate, or a plastic substrate. The third carrier substrate CS3 and the third adhesive material layer AM3 of the first redistribution structure 210 may be disposed therebetween.

Referring to FIG. 11E, a fourth redistribution structure 230 including a fourth redistribution pattern 233 and a fourth redistribution insulating layer 231 is formed on the package molding layer 241. For example, the fourth redistribution insulating layer 231 may be formed through a lamination process, and the fourth redistribution pattern 233 may be formed through a plating process. A method of forming the fourth redistribution structure 230 is substantially the same as or similar to the method of forming the first redistribution structure 210 described above, and thus a repeated description thereof is omitted here.

Referring to FIGS. 11E and 11F, the third carrier substrate CS3 is separated from the first redistribution structure 210 and external connection terminals 251 are attached to the lower side of the first redistribution structure 210. The external connection terminals 251 may be formed through a solder ball attach process and a reflow process.

Referring to FIGS. 11F and 11G, a sawing process of cutting the panel-shaped structure shown in FIG. 11F along a cutting line CL2 may be performed. Through the sawing process, the panel-shaped structure shown in FIG. 11F may be separated into individual ones of a plurality of the semiconductor package 2000.

While non-limiting example embodiments have been particularly shown and described with reference to the drawings, it will be understood that various changes in form and details may be made without departing from the spirit and scope of the present disclosure.

1. A semiconductor package comprising:
a first redistribution structure comprising a first redistribution pattern and a first redistribution insulating layer, wherein the first redistribution pattern comprises a first redistribution via extending in a vertical direction within the first redistribution insulating layer;
a second redistribution structure on the first redistribution structure and comprising a second redistribution pattern and a second redistribution insulating layer, wherein the second redistribution pattern comprises a lower redistribution pad at a lower surface of the second redistribution insulating layer;
a first semiconductor chip on the second redistribution structure; and
a second semiconductor chip on the first semiconductor chip,
wherein an upper surface of the first redistribution insulating layer is in contact with the lower surface of the second redistribution insulating layer, and
wherein the first redistribution via of the first redistribution structure is in contact with the lower redistribution pad of the second redistribution structure.

2. The semiconductor package of claim 1, further comprising:
a third redistribution structure that is between the first semiconductor chip and the second semiconductor chip and comprises a third redistribution pattern and a third redistribution insulating layer; and
a conductive post extending between the second redistribution structure and the third redistribution structure and electrically connecting the second redistribution pattern to the third redistribution pattern.

3. The semiconductor package of claim 2, further comprising:
a first connection bump between the first semiconductor chip and the second redistribution structure;
a conductive pillar between the first semiconductor chip and the third redistribution structure; and
a second connection bump between the second semiconductor chip and the third redistribution structure.

4. The semiconductor package of claim 3, further comprising a first molding layer between the second redistribution structure and the third redistribution structure,
wherein the first molding layer at least partially surrounds the first semiconductor chip, the first connection bump, and the conductive pillar,
wherein the conductive post vertically penetrates the first molding layer.

5. The semiconductor package of claim 4, wherein an upper surface of the first molding layer is coplanar with an upper surface of the conductive pillar.

6. The semiconductor package of claim 4, further comprising a second molding layer at least partially surrounding the second semiconductor chip on the third redistribution structure.

7. The semiconductor package of claim 6, wherein an upper surface of the second molding layer is coplanar with an upper surface of the second semiconductor chip.

8. The semiconductor package of claim 1, wherein the first semiconductor chip comprises:
a first semiconductor substrate comprising a first active surface and a first inactive surface that are opposite to each other, wherein the first active surface faces towards the second semiconductor chip;
a first through electrode penetrating the first semiconductor substrate;
a first front-side interconnect structure on the first active surface of the first semiconductor substrate and comprising a first interconnect pattern electrically connected to the first through electrode; and
a first backside interconnect structure between the first inactive surface of the first semiconductor substrate and the second redistribution structure and comprising a first backside interconnect pattern, the first backside interconnect structure electrically connected to the first through electrode.

9. The semiconductor package of claim 8, wherein the second semiconductor chip comprises:
a second semiconductor substrate comprising a second active surface and a second inactive surface that are opposite to each other, wherein the second active surface faces towards the first semiconductor chip; and
a second interconnect structure between the second active surface of the second semiconductor substrate and the first semiconductor chip and comprising a second interconnect pattern.

10. The semiconductor package of claim 1, further comprising:
a frame substrate on an outer portion of the first redistribution structure and comprising a frame body and a vertical connection conductor in the frame body, wherein the frame body has a through hole that accommodates the first semiconductor chip and the second semiconductor chip; and
a third molding layer on the first semiconductor chip and the second semiconductor chip within the through hole of the frame substrate.

11. The semiconductor package of claim 10, further comprising a fourth redistribution structure on the third molding layer and comprising a fourth redistribution pattern electrically connected to the vertical connection conductor.

12. The semiconductor package of claim 11, further comprising a third semiconductor chip on the fourth redistribution structure.

13. The semiconductor package of claim 1, further comprising:
a third molding layer on the first semiconductor chip and the second semiconductor chip;
a vertical connection conductor penetrating the third molding layer; and
a fourth redistribution pattern extending on the third molding layer and electrically connected to the vertical connection conductor.

14. A semiconductor package comprising:
a first redistribution structure comprising a first redistribution pattern and a first redistribution insulating layer, wherein the first redistribution pattern comprises a first redistribution via extending in a vertical direction from an upper surface of the first redistribution insulating layer;
a sub package on a central portion of the first redistribution structure;
a frame substrate on an outer portion of the first redistribution structure and comprising a frame body having a through hole accommodating the sub package, and the frame substrate further comprising a vertical connection conductor extending in the vertical direction within the frame body; and
a package molding layer on the sub package within the through hole of the frame substrate,
wherein the sub package comprises:
a second redistribution structure comprising a second redistribution pattern and a second redistribution insulating layer, wherein the second redistribution pattern comprises a lower redistribution pad at a lower surface of the second redistribution insulating layer;
a first semiconductor chip on the second redistribution structure;
a first molding layer at least partially surrounding the first semiconductor chip on the second redistribution structure;
a third redistribution structure on the first semiconductor chip and the first molding layer and comprising a third redistribution pattern and a third redistribution insulating layer;
a conductive post extending between the second redistribution structure and the third redistribution structure and electrically connecting the second redistribution pattern to the third redistribution pattern; and
a second semiconductor chip on the third redistribution structure,
wherein the upper surface of the first redistribution insulating layer is in direct contact with the lower surface of the second redistribution insulating layer, and
wherein the first redistribution via of the first redistribution structure is in direct contact with the lower redistribution pad of the second redistribution structure.

15. The semiconductor package of claim 14, wherein a sidewall of the second redistribution structure, a sidewall of the first molding layer, and a sidewall of the third redistribution structure are aligned with each other in the vertical direction, wherein the package molding layer extends along the sidewall of the second redistribution structure, the sidewall of the first molding layer, and the sidewall of the third redistribution structure.

16. The semiconductor package of claim 15, further comprising:
a first connection bump between the first semiconductor chip and the second redistribution structure and electrically connecting the first semiconductor chip to the second redistribution pattern;
a conductive pillar between the first semiconductor chip and the third redistribution structure and electrically connecting the first semiconductor chip and the third redistribution pattern;
a second connection bump between the second semiconductor chip and the third redistribution structure and electrically connecting the second semiconductor chip to the third redistribution pattern; and
a second molding layer at least partially surrounding the second semiconductor chip on the third redistribution structure,
wherein a sidewall of the second molding layer is aligned with a sidewall of the third redistribution structure in the vertical direction, and
wherein the package molding layer extends along the sidewall of the second molding layer.

17. The semiconductor package of claim 16, wherein the first molding layer at least partially surrounds the first semiconductor chip, the first connection bump, and the conductive pillar,
wherein an upper surface of the first molding layer is coplanar with an upper surface of the conductive pillar.

18. The semiconductor package of claim 15, wherein the package molding layer directly contacts a sidewall of the second semiconductor chip and extends along the sidewall of the second semiconductor chip.

19. A semiconductor package comprising:
a first redistribution structure comprising a first redistribution pattern and a first redistribution insulating layer, wherein the first redistribution pattern comprises a first redistribution via extending in a vertical direction from an upper surface of the first redistribution insulating layer;
a sub package on a central portion of the first redistribution structure;
a frame substrate on an outer portion of the first redistribution structure and comprising a frame body having a through hole accommodating the sub package, and the frame substrate further comprising a vertical connection conductor extending in the vertical direction within the frame body; and
a package molding layer on the sub package within the through hole of the frame substrate,
wherein the sub package comprises:
a second redistribution structure comprising a second redistribution pattern and a second redistribution insulating layer, wherein the second redistribution pattern comprises a lower redistribution pad at a lower surface of the second redistribution insulating layer and a second redistribution via extending in the vertical direction within the second redistribution insulating layer;
a first semiconductor chip on the second redistribution structure;
a first connection bump electrically connecting the second redistribution pattern to the first semiconductor chip between the second redistribution structure and the first semiconductor chip;
a first molding layer at least partially surrounding the first semiconductor chip on the second redistribution structure;
a third redistribution structure on the first semiconductor chip and the first molding layer and comprising a third redistribution pattern and a third redistribution insulating layer;
a conductive post extending between the second redistribution structure and the third redistribution structure and electrically connecting the second redistribution pattern to the third redistribution pattern;
a second semiconductor chip on the third redistribution structure;
a second connection bump electrically connecting the third redistribution pattern to the second semiconductor chip between the third redistribution structure and the second semiconductor chip; and
a second molding layer at least partially surrounding the second semiconductor chip on the third redistribution structure,
wherein the upper surface of the first redistribution insulating layer is in direct contact with the lower surface of the second redistribution insulating layer,
wherein the first redistribution via directly contacts the lower redistribution pad of the second redistribution structure,
wherein the first redistribution via has a tapered shape in which a width thereof decreases towards the upper surface of the first redistribution insulating layer, and
wherein the lower redistribution pad has a rectangular cross-sectional shape.

20. The semiconductor package of claim 19, wherein the first redistribution structure further comprises a first seed metal layer extending along a surface of the first redistribution via,
wherein the second redistribution structure further comprises a second seed metal layer extending along a lower surface of the lower redistribution pad,
wherein the first seed metal layer and the second seed metal layer are in contact with each other.
